(19) United States
(12) Patent Application Publication
(10) Pub. No.: US 2007/0057368 A1
(43) Pub. Date: Mar. 15, 2007

(54) Semiconductor package having plate interconnections

(76) Inventors: Yueh-Se Ho, Sunnyvale, CA (US); Ming Sun, Sunnyvale, CA (US)

Correspondence Address: FORTUNE LAW GROUP LLP, 100 CENTURY CENTER COURT, SUITE 315, SAN JOSE, CA, 95112, US

(21) Appl. No.: 11/226,913

(22) Filed: Sep. 13, 2005

(51) Int. Cl. H01L 23/48; H01L 23/28

(52) U.S. Cl. 257/735; 257/787; 257/E23.014

(57) ABSTRACT

A semiconductor package is disclosed. The package includes a leadframe having drain, source and gate leads, a semiconductor die coupled to the leadframe, the semiconductor die having metalized source and gate areas separated by a passivation area, a patterned source connection coupling the source lead to the semiconductor die metalized source area, a patterned gate connection coupling the gate lead to the semiconductor die metalized gate area, a semiconductor die drain area coupled to the drain lead and an encapsulant covering at least a portion of the semiconductor die and drain, source and gate leads.

### BACKGROUND OF THE INVENTION

The present invention generally relates to a semiconductor package and more particularly to a semiconductor package having plate interconnections between power semiconductor device source and gate metalized areas and leadframe source and gate leads.

Semiconductor devices are conventionally connected to leadframe leads using either plate interconnections or wire bonding. For example, U.S. Pat. No. 5,821,611 discloses a semiconductor device which comprises a first lead having a tip formed with an island, a semiconductor chip unit mounted on the island of the first lead by means of a solder layer and having a plurality of electrode bumps projecting away from the island, and a plurality of additional leads each of which has a tip electrically connected to the electrode bumps via respective solder deposits. The additional leads include at least second and third leads. The leads are alloyed to the electrode bumps in a heating furnace and the solder bumps may spread during heating and create undesirable shapes.

U.S. Pat. No. 6,040,626 discloses a semiconductor package which employs a mixed connection between a MOSFET top surface comprising a low resistance plate portion for connecting to a source and a wire bond for connecting to a gate. Wire bonding may introduce short circuits in the device due to device dialectric layer damage during the wire bonding process.

A semiconductor package with directly connected leads is disclosed in U.S. Pat. No. 6,249,041. A semiconductor device includes a semiconductor chip with contact areas on the top or bottom surface. A first lead assembly, formed from a semi-rigid sheet of conductive material, has a lead assembly contact attached to one of the contact areas of the semiconductor chip. The first lead assembly also has at least one lead connected to and extending from the lead assembly contact. A second lead assembly, also formed from a semi-rigid sheet of conductive material, has a lead assembly contact attached to another one of the contact areas of the semiconductor chip. The second lead assembly also has at least one lead connected to and extending from the lead assembly contact. An encapsulant encloses the semiconductor chip, the lead assembly contact of the first lead assembly and the lead assembly contact of the second lead assembly. The semiconductor device has low electrical and thermal resistance contributions from the package due to the direct connection of the lead assemblies to the chip. The lead assembly contact areas are held in contact with lead contact areas on the semiconductor chip by an electrically conductive adhesive layer. The electrically conductive adhesive layer may be a silver-filled epoxy or polyimide paste or solder bumps. The adhesive layer may be cured in a curing oven, if necessary. The adhesive layer does not include soft solder or solder paste.

Another semiconductor package with directly connected leads is disclosed in U.S. Pat. No. 6,479,888. A MOSFET comprises a plurality of inner leads electrically connected to a surface electrode of a semiconductor pellet having a field effect transistor on a principal surface thereof. The inner leads are mechanically and electrically connected to the principal surface by a gate connecting portion and source connecting portions constituted by bumps.

There is therefore a need in the art for a semiconductor package that includes a semiconductor power device connected to leadframe source and gate leadframe contact areas by means of patterned plates. There is also a need for a semiconductor package having device passivation areas for restricting the flow of solder during the soldering process. There is also a need for a metalized area formed of Ni/Au. There is also a need for a semiconductor package process that increases throughput. There is also a need for a semiconductor package method that provides a soft attachment process of the patterned plates onto the semiconductor power device. There is also a need for a semiconductor package having an exposed source plate. There is also a need for a semiconductor package having reduced electrical resistance. There is a further need for a semiconductor package having improved thermal dissipation properties. There is also a need for a semiconductor package having improved mechanical properties.

### SUMMARY OF THE INVENTION

The present invention overcomes the limitations of the prior art by providing a semiconductor device package having plate connections between leadframe source and gate contact areas and a power semiconductor power device source and gate metalized areas. A portion of the source plate may be exposed to allow for improved thermal dissipation.

In accordance with another aspect of the invention, a semiconductor package includes a leadframe having drain, source and gate leads, a semiconductor die coupled to the leadframe, the semiconductor die having metalized source and gate areas, a patterned source connection coupling the source lead to the semiconductor die metalized source area, a patterned gate connection coupling the gate lead to the semiconductor die metalized gate area a semiconductor die drain passivation area coupled to the drain lead, and an encapsulant covering at least a portion of the semiconductor die and drain, source and gate leads.

In accordance with yet another aspect of the invention, a semiconductor package includes a leadframe having drain, source and gate leads, a semiconductor die coupled to the leadframe, the semiconductor die having Ni/Au metalized source and gate areas, a patterned source connection coupling the source lead to the semiconductor die metalized source area, the patterned source connection being soldered to the semiconductor die metalized source area, a patterned gate connection coupling the gate lead to the semiconductor die metalized gate area, the patterned gate connection being soldered to the semiconductor die metalized gate area, a semiconductor die metalized drain area coupled to the drain lead, and an encapsulant covering at least a portion of the semiconductor die and drain, source and gate leads.

In accordance with another aspect of the invention, a semiconductor package having a gate clip locked to a semiconductor die metalized gate area includes a leadframe having drain, source and gate leads, a semiconductor die coupled to the leadframe, the semiconductor die having metalized source and gate areas, a source clip coupling the source lead to the semiconductor die metalized source passivation area, a semiconductor die metalized drain area coupled to the drain lead, an encapsulant covering at least a portion of the semiconductor die and drain source and gate leads, and wherein the gate clip couples the gate lead to the semiconductor die metalized gate area through an aperture formed in the gate clip.

There has been outlined, rather broadly, the more important features of the invention in order that the detailed description thereof that follows may be better understood, and in order that the present contribution to the art may be better appreciated. There are, of course, additional features of the invention that will be described below and which will form the subject matter of the claims appended herein.

In this respect, before explaining at least one embodiment of the invention in detail, it is to be understood that the invention is not limited in its application to the details of design and to the arrangement of components set forth in the following description or illustrated in the drawings. The invention is capable of other embodiments and of being practiced and carried out in various ways. Also, it is to be understood that the phraseology and terminology employed herein, as well as the abstract, are for the purpose of description and should not be regarded as limiting.

As such, those skilled in the art will appreciate that the conception upon which this disclosure is based may readily be utilized as a basis for the designing of other methods and systems for carrying out the several purposes of the present invention. It is important, therefore, that the claims be regarded as including such equivalent methods and systems insofar as they do not depart from the spirit and scope of the present invention.

### BRIEF DESCRIPTION OF THE DRAWINGS

FIG. 1 is schematic representation of a semiconductor package in accordance with the invention;

FIG. 2 is a cross sectional view of the semiconductor package of FIG. 1 taken along line 2-2 in accordance with the invention:

FIG. 3 is a cross sectional view of the semiconductor package of FIG. 1 taken along line 3-3 in accordance with the invention;

FIG. 3A is a schematic representation of a patterned gate connection disposed over a metalized gate area in accordance with the invention;

FIG. 3B is a schematic representation of a gate lock in accordance with the invention;

FIG. 3C is a schematic representation of the semiconductor package of FIG. 1 showing an alternative metalized gate area in accordance with the invention;

FIG. 4 is a view in partial section of the semiconductor package of FIG. 1 in accordance with the invention;

FIG. 5 is another view in partial section of the semiconductor package of FIG. 1 in accordance with the invention;

FIG. 6 is a schematic representation of an alternative embodiment of the semiconductor package in accordance with the invention;

FIG. 7 is a cross sectional view of the semiconductor package of FIG. 6 taken along line A-A in accordance with the invention;

FIG. 8 is a cross sectional view of the semiconductor package of FIG. 6 taken along line B-B in accordance with the invention;

FIG. 9 is a view in partial section of the semiconductor package of FIG. 6 in accordance with the invention;

FIG. 10 is a schematic representation of an alternative embodiment of the semiconductor package in accordance with the invention;

FIG. 11 is a cross sectional view of the semiconductor package of FIG. 10 taken along line A-A in accordance with the invention; and

FIG. 12 is a cross sectional view of the semiconductor package of FIG. 10 taken along line B-B in accordance with the invention.

### DETAILED DESCRIPTION OF THE INVENTION

The following detailed description is of the best modes of carrying out the invention. The description is not to be taken in a limiting sense, but is made merely for the purpose of illustrating the general principles of the invention; since the scope of the invention is best defined by the appended claims.

The present invention generally provides a semiconductor device package having plate connections between leadframe source and gate contact areas and power semiconductor power device metalized source and gate areas. The metalized source and gate passivation areas are preferably Ni/Au plated or sputtered surfaces. The metalized source and gate areas provide for improved bonding of the plate connections and reduction of overbonding which often introduces short circuit problems due to dielectric layer damage during wire bonding processes. The metalized source and gate areas further eliminate the need for solder bumps and epoxy adhesive layers as soft solder and solder paste may be used to connect the plates to the metalized source and gate areas.

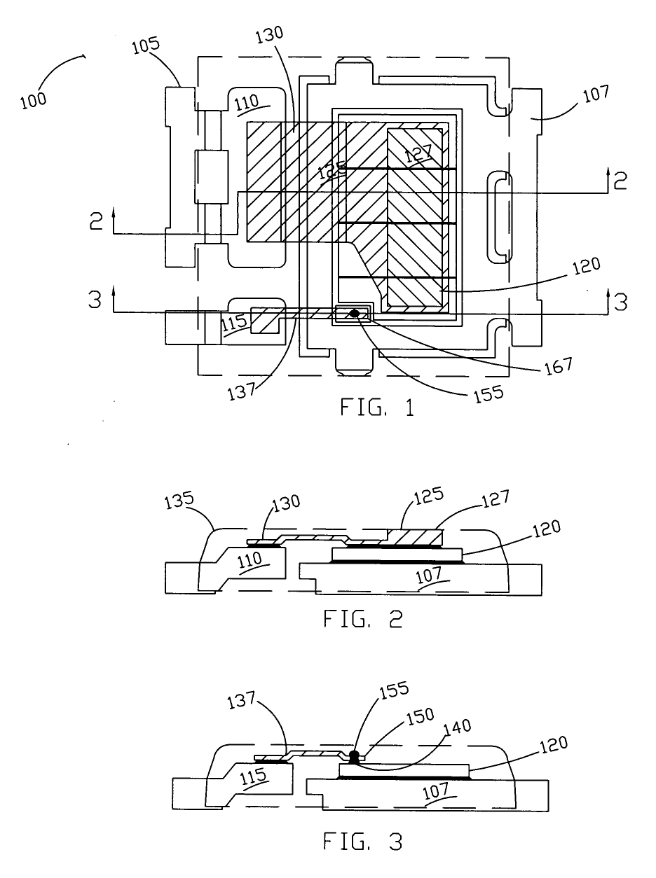

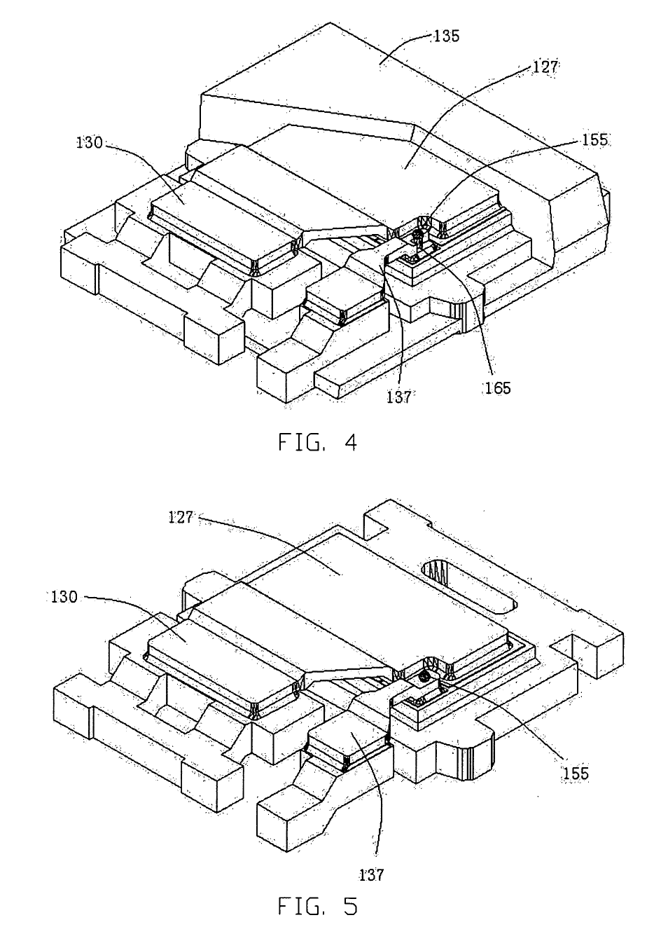

In a first aspect of the invention and with reference to FIGS. 1-5, a semiconductor package generally designated 100 may include a leadframe 105 having a drain contact portion 107, a source contact portion 110 and a gate contact portion 115. A power semiconductor die 120 may have a metalized drain area (not shown) coupled to the drain contact portion 107 by solder reflow.

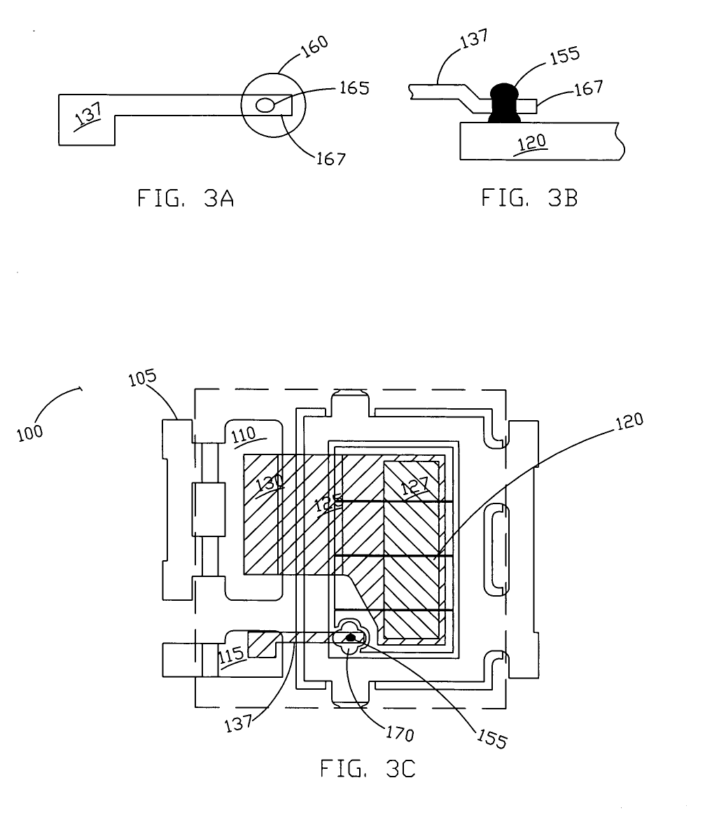

Semiconductor source and gate metalized areas may be formed by Ni/Au plating or sputtering. With reference to FIG. 3A, a gate metalized area 160 may be of circular configuration. It has been discovered by the inventors that circular metalized area 160 advantageously restricts the flow of soft solder and solder paste to the confines of the circular metalized area 160 during solder reflow, thereby reducing the incidence of undesirable shapes and short circuits.

A patterned source plate 125 may include an exteriorly exposed portion 127 and an internal portion 130. Interior portion 130 may be coupled to source contact portion 110. Exteriorly exposed portion 127 may be exposed outside of an encapsulant 135. Patterned source plate 125 may be coupled to the metalized source area by solder reflow using soft solder or solder paste. Metalized source area may cover a substantial portion of a top surface of the die 120 for improved heat dissipation and decreased resistance and inductance.

A patterned gate plate 137 may connect the metalized gate area 160 to the leadframe gate contact area 115. The patterned gate plate 137 may include a hole 165 formed at an end 167 thereof. A locking ball 155 may be formed during solder reflow to provide mechanical stability to the patterned gate plate 137 (FIG. 3B). In one aspect of the invention, soft solder may be disposed in the hole 165 and allowed to flow through the hole 165 to the metalized gate area 160 during solder reflow. Metalized gate area 160 may provide a bonding surface for the solder which limits the flow of solder to the circular area.

With reference to FIG. 3C, an alternative metalized gate area 170 is shown including a cross-shaped area.

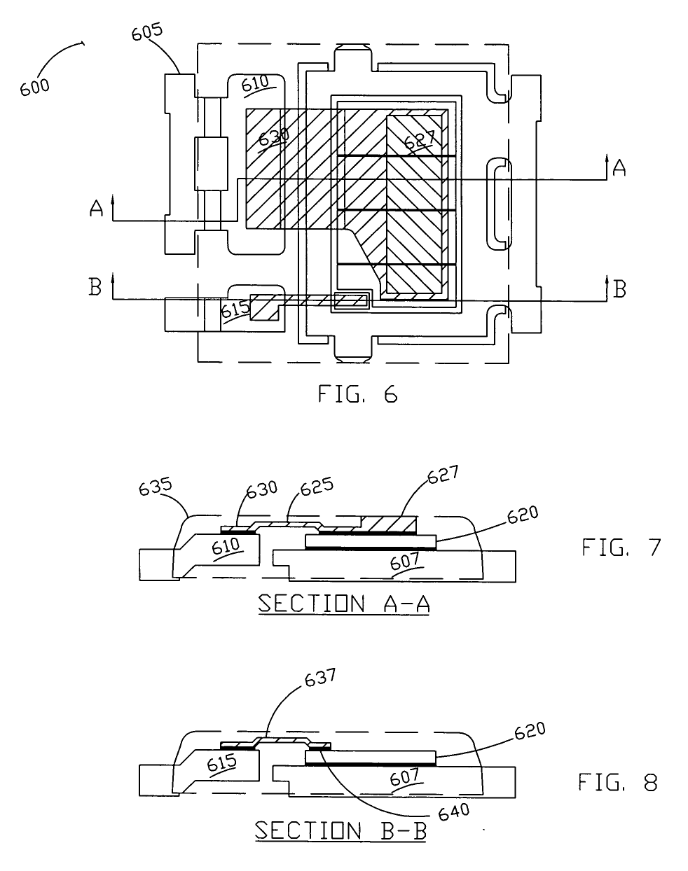

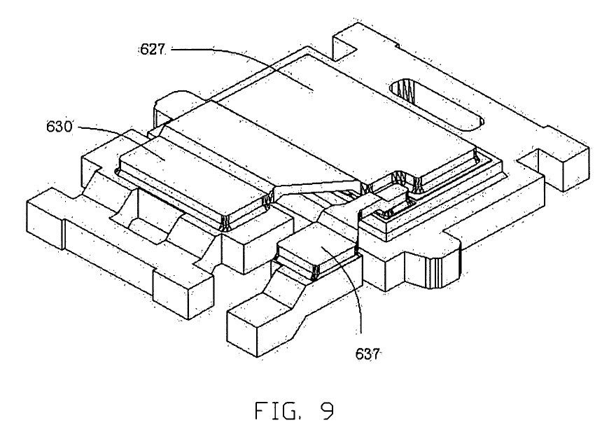

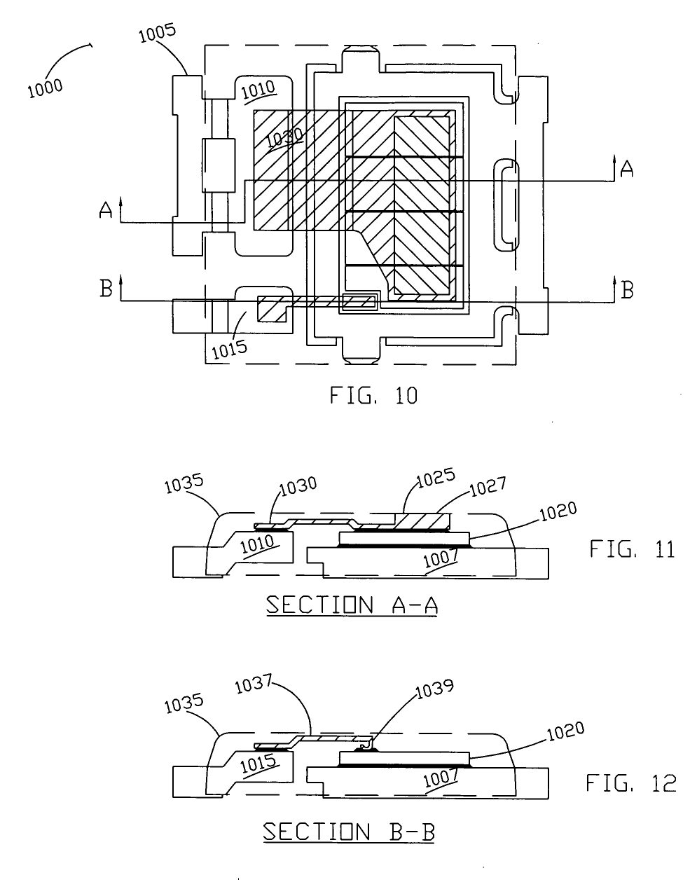

In accordance with another aspect of the invention, and as shown in FIGS. 6-9, a semiconductor package generally designated 600 may include a leadframe 605 having a drain contact portion 607, a source contact portion 610 and a gate contact portion 615. A power semiconductor die 620 may have a metalized drain area (not shown) coupled to the drain contact portion 607 by solder reflow.

Semiconductor source and gate metalized areas may be formed by Ni/Au plating or sputtering. A patterned source plate 625 may include an exteriorly exposed portion 627 and an internal portion 630. Exteriorly exposed portion 627 may be exposed outside of an encapsulant 635. Patterned source plate 625 may be coupled to the metalized source area by solder reflow using soft solder or solder paste.

A patterned gate plate 637 may connect the metalized gate area 640 to the leadframe gate contact area. The patterned gate plate 637 may be connected to the metalized gate area 640 by solder reflow to provide mechanical stability to the patterned gate plate 637.

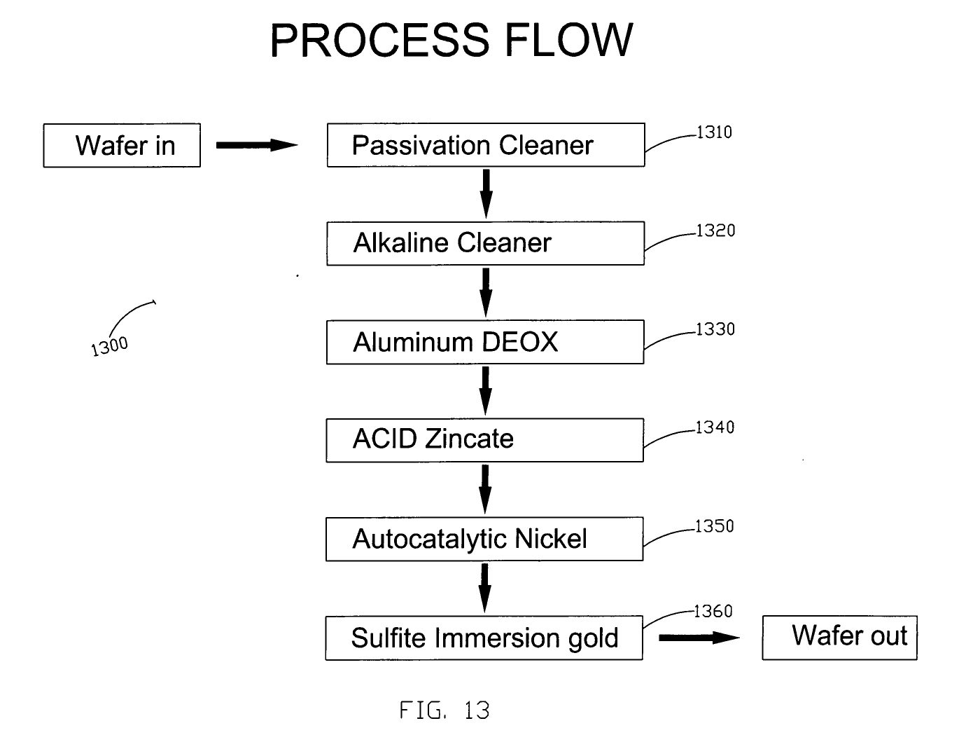

In another aspect of the invention and with reference to FIGS. 10-12, a semiconductor package generally designated 1000 may include a leadframe 1005 having a drain contact portion 1007, a source contact portion 1010 and a gate contact portion 1015. A power semiconductor die 1020 may have a metalized drain area (not shown) coupled to the drain contact portion 1007 by solder reflow.

Semiconductor source and gate metalized areas may be formed by Ni/Au plating or sputtering. A patterned source plate 1025 may include an exteriorly exposed portion 1027 and an internal portion 1030. Exteriorly exposed portion 1027 may be exposed outside of an encapsulant 1035. Patterned source plate 1025 may be coupled to the metalized source area by solder reflow using soft solder or solder paste.

A patterned gate plate 1037 may connect the metalized gate area 1040 to the leadframe gate contact area. Patterned gate plate 1037 may include a hook portion 1039 for connection to the metalized gate area 1040. The patterned gate plate 1037 may be connected to the metalized gate area 1040 by solder reflow to provide mechanical stability to the patterned gate plate 1037

The present invention advantageously employs Ni/Au device patterned source, drain and gate metalized areas. Ni/Au provides for improved connection between the patterned source plates and patterned gate plates and allows for a simplified process of source, drain and gate metallization in one Ni/Au process to thereby improve process throughput.

The Ni/Au process provides for a Ni layer on the metal areas and a Au layer to protect the Ni layer. As Ni does not diffuse into the Al metal area, an inter-metallic layer comprised of Ni/Al provides for a high density layer to which the patterned source and gate connections may be soldered.

The present invention advantageously provides for patterned source and gate plate connections. The exposed source plate advantageously provides for improved thermal dissipation. The gate plate advantageously provides for improved mechanical connection between the gate metalized area and the leadframe gate contact area. As wire bonding is not needed to couple the gate to the leadframe gate contact area, the gate plate and the source plate can be connected in a single process. The metalized areas can be patterned and insulated by a passivation area to prevent solder spreading during solder reflow.

It should be understood, of course, that the foregoing relates to preferred embodiments of the invention and that modifications may be made without departing from the spirit and scope of the invention as set forth in the following claims.

We claim:

1. A semiconductor package comprising:
a leadframe having drain, source and gate leads;
a semiconductor die coupled to the leadframe the semiconductor die having metalized source and gate areas:
a patterned source connection coupling the source lead to the semiconductor die metalized source area;
a patterned gate connection coupling the gate lead to the semiconductor die metalized gate area;
a semiconductor die drain area coupled to the drain lead; and
an encapsulant covering at least a portion of the semiconductor die and drain, source and gate leads.

2. The semiconductor package of claim 1, wherein a portion of the patterned source connection is exposed through the encapsulant.

3. The semiconductor package of claim 1, wherein the patterned gate connection comprises an opening through which the patterned gate connection is soldered to the metalized gate area.

4. The semiconductor package of claim 3, wherein the solder forms a lock at a top portion of the patterned gate connection.

5. The semiconductor package of claim 1, wherein the patterned gate connection and the patterned source connection are soldered to the metalized gate area and the metalized source area respectively.

6. The semiconductor package of claim 1, wherein the patterned gate connection comprises a hooked portion at an end thereof.

7. The semiconductor package of claim 1, wherein the patterned gate connection comprises a flat portion at an end thereof.

8. The semiconductor package of claim 1, wherein the metalized source and gate areas comprise circular metalized areas insulated by passivation areas.

9. The semiconductor package of claim 1, wherein the metalized source and gate areas comprise an upper Ni/Au layer.

10. The semiconductor package of claim 1, wherein the drain area comprises a metalized drain area.

11. The semiconductor package of claim 10, wherein the metalized drain area comprises an upper NI/Au layer.

12. The semiconductor package of claim 1, wherein a bottom portion of the drain lead is exposed through the encapsulant.

13. A semiconductor package comprising:
a leadframe having drain, source and gate leads;
a semiconductor die coupled to the leadframe; the semiconductor die having Ni/Au metalized source and gate areas;
a patterned source connection coupling the source lead to the semiconductor die metalized source area, the patterned source connection being soldered to the semiconductor die metalized source area;
a patterned gate connection coupling the gate lead to the semiconductor die metalized gate area, the patterned gate connection being soldered to the semiconductor die metalized gate area;
a semiconductor die drain area coupled to the drain lead; and
an encapsulant covering at least a portion of the semiconductor die and drain, source and gate leads.

14. The semiconductor package of claim 13, wherein a portion of the patterned source connection is exposed through the encapsulant.

15. The semiconductor package of claim 13, wherein the patterned gate connection comprises an opening through which the patterned gate connection is soldered to the metalized gate area.

16. The semiconductor package of claim 15, wherein the solder forms a lock at a top portion of the patterned gate connection.

17. A semiconductor package having a gate clip locked to a semiconductor die metalized gate passivation area comprising:
a leadframe having drain, source and gate leads;
a semiconductor die coupled to the leadframe, the semiconductor die having metalized source and gate areas;
a source clip coupling the source lead to the semiconductor die metalized source area;
a semiconductor die drain area coupled to the drain lead;
an encapsulant covering at least a portion of the semiconductor die and drain, source and gate leads; and
wherein the gate clip couples the gate lead to the semiconductor die metalized gate area through an aperture formed in the gate clip.

18. The semiconductor package of claim 17, wherein a portion of the patterned source connection is exposed through the encapsulant.

19. The semiconductor package of claim 17, wherein the gate clip and the source clip are soldered to the metalized gate area and the metalized source area respectively the gate clip solder forming the lock.

20. The semiconductor package of claim 17, wherein the metalized source and gate areas comprise an upper Ni/Au layer.
